(19) United States
(12) Patent Application Publication
(10) Pub. No.: US 2026/0247070 A1
(43) Pub. Date: Aug. 20, 2026

(54) DISPLAY DEVICE, DISPLAY MODULE AND SOUND PRODUCING DEVICE

(71) Applicant: BOE Technology Group Co., Ltd., Beijing (CN)

(72) Inventor: Mingche HSIEH, Beijing (CN)

(21) Appl. No.: 18/859,744

(22) PCT Filed: Jan. 3, 2024
(86) PCT No.: PCT/CN2024/070317

§ 371 Date: Oct. 24, 2024

(30) Foreign Application Priority Data
Jan. 16, 2023 (CN) 202310077268.4

(51) Int. Cl. H04R 1/40; H04R 3/12; H10K 59/80; H10K 77/10; H10K 102/00

(52) U.S. Cl. CPC H04R 1/403; H04R 3/12; H10K 59/873; H10K 59/8791; H10K 77/111; H04R 2499/15; H10K 2102/311

(57) ABSTRACT

The present disclosure provides a display device, a display module and a sound producing device. The sound producing device includes a plurality of transducer arrays each including a plurality of transducers; and a plurality of driving circuits correspondingly and electrically connected with the plurality of transducer arrays, and the plurality of transducers in one transducer array being connected to the same driving circuit; where the driving circuits are configured to send preset signals to corresponding transducer arrays, the transducer arrays are configured to respond to the preset signals and emit sound waves, and the sound wave directions of the sound waves emitted by two transducer arrays in the plurality of transducer arrays are different. range

### TECHNICAL FIELD

The present disclosure relates to the field of display technologies, and in particular, to a display device, a display module and a sound producing device.

### BACKGROUND

With the development of technology, sound producing devices have attracted more and more attention. However, some existing sound producing devices still need to be improved.

### SUMMARY

An object of the present disclosure is to provide a display device, a display module and a sound producing device, which can broaden an application range of the sound producing device.

According to an aspect of the present disclosure, there is provided a sound producing device, including:

a plurality of transducer arrays, each transducer array including a plurality of transducers;

a plurality of driving circuits respectively electrically connected with the plurality of transducer arrays, and the plurality of transducers in one of the transducer arrays are connected with a same driving circuit;

the plurality of driving circuits are respectively configured to send preset signals to corresponding transducer arrays, the plurality of transducer arrays are configured to respond to the preset signals and emit sound waves, and sound wave directions of sound waves emitted by two transducer arrays in the plurality of transducer arrays are different.

In some embodiments, the plurality of transducer arrays include a first transducer array and a plurality of second transducer arrays, the plurality of second transducer arrays surround the first transducer array, and a number of transducers in the first transducer array is greater than a number of transducers in the second transducer array.

In some embodiments, each of the plurality of driving circuits includes:

a modulation sub-circuit configured to receive a modulation signal and a carrier signal and output a modulated signal according to the modulation signal and the carrier signal;

a power amplification sub-circuit configured to receive the modulated signal and output the preset signal according to the modulated signal.

In some embodiments, the sound producing device further includes:

a position detection device configured to acquire position information of a target object;

a processor, electrically connected with the position detection device and the plurality of driving circuits, and configured to control to control the plurality of driving circuits to send the preset signals to the plurality of transducer arrays according to the position information, such that the plurality of transducer arrays send sound waves toward the target object.

According to an aspect of the present disclosure, there is provided a display module including the sound producing device.

In some embodiments, each transducer of the plurality of transducers includes a first electrode, a second electrode and a vibration film, where the first electrode and the second electrode are disposed opposite to each other and are spaced apart from each other, a space between the first electrode and the second electrode forms a vibration cavity of the transducer, and the display module includes:

a substrate;

a display structure on the substrate, the display structure being provided with a plurality of first through holes exposing the substrate, the plurality of first through holes correspondingly forming vibration cavities of the plurality of transducers;

where the first electrode is in a region of the substrate exposed through the first through hole; the vibration film is on the display structure and away from the substrate and covers the first through hole; and the second electrode is on the vibration film facing or facing away from the display structure and in a region of the vibration film corresponding to the first through hole.

In some embodiments, each driving circuit of the plurality of driving circuits is electrically connected with the second electrode through a first wiring, and a partial region of the first wiring is between the vibration film and the display structure.

In some embodiments, the plurality of transducers share one vibration film, and the vibration film includes a polarizer and/or a cover plate.

In some embodiments, the display module includes a display area and a peripheral area, the plurality of driving circuits are in the peripheral area, and at least part of the plurality of transducers are in the display area.

In some embodiments, each transducer of the plurality of transducers includes a first electrode, a second electrode and a vibration film, where the first electrode and the second electrode are disposed opposite to each other and are spaced apart from each other, a space between the first electrode and the second electrode forms a vibration cavity of the transducer, and the display module includes:

a substrate;

a display structure on the substrate, the display structure forming at least part of the vibration film, the first electrode being on the substrate and away from the display structure; and

a support structure on the first electrode and away from the display structure, where the support structure is provided with a plurality of second through holes exposing the first electrode, and each second through hole forms a vibration cavity of the transducer; where the second electrode is on the support structure and away from the substrate and covers the second through hole.

In some embodiments, the display module includes:

a stress relief layer on the support structure and away from the substrate; and

a stainless steel support layer on the stress relief layer and away from the substrate.

In some embodiments, a thickness of the support structure is 5 μm-20 μm; and/or

a distance between a surface of the stress relief layer facing the substrate and a surface of the stainless steel support layer away from the substrate is 150 μm-300 μm.

In some embodiments, the display structure includes:

a flexible substrate on the substrate;

a pixel circuit layer on the flexible substrate and away from the substrate;

a plurality of organic electroluminescent devices on the pixel circuit layer and away from the flexible substrate;

a pixel defining layer surrounding the plurality of organic electroluminescent devices;

an encapsulation layer covering the plurality of organic electroluminescent devices; and

the display module further comprises a polarizer on the encapsulation layer and away from the flexible substrate.

In some embodiments, a distance between a surface of the flexible substrate facing the substrate and a surface of the polarizer away from the substrate is 50 μm-200 μm.

In some embodiments, the vibration cavities of the plurality of transducers in one of the transducer arrays are communicated; and/or

the vibration cavities of the plurality of transducers in different transducer arrays are not communicated.

According to an aspect of the present disclosure, there is provided a display device including the display module.

According to the display device, the display module and the sound producing device, the plurality of driving circuits are correspondingly and electrically connected with the plurality of transducer arrays, the driving circuits are respectively configured to send preset signals to the corresponding transducer arrays, the transducer arrays are configured to respond to the preset signals and emit sound waves, and in the use process, the plurality of driving circuits send the same or different preset signals to the plurality of transducer arrays, such that the sound wave directions of the sound waves emitted by the plurality of transducer arrays are different, thereby broadening the application range of the sound producing device.

### BRIEF DESCRIPTION OF DRAWINGS

FIG. 1 is a schematic diagram of a sound producing device according to embodiments of the present disclosure.

FIG. 2 is a schematic diagram of a driving circuit and a transducer array according to embodiments of the present disclosure.

FIG. 3 is another schematic diagram of a sound producing device according to embodiments of the present disclosure.

FIG. 4 and FIG. 5 are schematic diagrams of sound waves emitted by a sound producing device according to embodiments of the present disclosure.

FIG. 6 is a schematic diagram of a position detection device, a processor, a driving circuit and a transducer array in embodiments of the present disclosure.

FIG. 7 and FIG. 8 are schematic diagrams of a display module according to embodiments of the present disclosure.

Reference numerals: 1, substrate; 2, flexible substrate; 3, buffer layer; 4, active layer; 5, first gate electrode layer; 6, second gate electrode layer; 7, source-drain electrode layer; 8, first gate insulation layer; 9, second gate insulation layer; 10, light emitting device; 101, anode; 102, light emitting layer; 103, cathode; 11, first electrode; 12, second electrode; 13, interlayer insulation layer; 14, planarization layer; 15, pixel defining layer; 16, encapsulation layer; 17, vibration film; 18, first through hole; 19, second through hole; 20, support structure; 21, stainless steel support layer; 22, driving circuit; 221, modulation sub-circuit; 222, power amplification sub-circuit; 23, transducer array; 231, transducer; 232, first transducer array; 233, second transducer array; 24, position detection device; 25, processor; 26, polarizer; 27, cover plate; 28, first wiring; 29, stress relief layer.

### DETAILED DESCRIPTION

Exemplary embodiments will be described in detail herein, examples of which are illustrated in the accompanying drawings. The following description refers to the drawings, unless otherwise indicated, like numerals in different drawings indicate the same or similar elements. The embodiments described in the following exemplary embodiments do not represent all embodiments consistent with the present disclosure. Rather, they are merely examples of devices consistent with some aspects of the present disclosure as detailed in the appended claims.

The term used in this disclosure is for the purpose of describing particular embodiments only and is not intended to limit this disclosure. Unless otherwise defined, technical terms or scientific terms used in the present disclosure shall be the general meanings understood by those skilled in the art to which the present disclosure belongs. “First” “second” and similar words used in the specification and claims of the present disclosure do not denote any order, quantity or importance, but are merely used to distinguish different components. Likewise, words such as “a” or “an” do not indicate a quantity limitation, but indicate that there is at least one. “A plurality of” or “several” means two or more. Unless otherwise indicated, words such as “front,” “rear,” “lower,” and/or “upper” are for ease of illustration only and are not limited to one position or one spatial orientation. Like words such as “include” or “comprise” mean that elements or objects appearing before “include” or “comprise” cover elements or objects listed after “include” or “comprise” and equivalents thereof, and do not exclude other elements or objects. The terms “connect” or “link” and the like are not limited to physical or mechanical connections, and may include electrical connections, whether direct or indirect. The singular forms “a”, “an” and “the” used in the specification of the present disclosure and the appended claims are also intended to include plural forms unless the context clearly indicates other meanings. It should also be understood that the term “and/or” as used herein refers to and encompasses any or all possible combinations of one or more associated listed items.

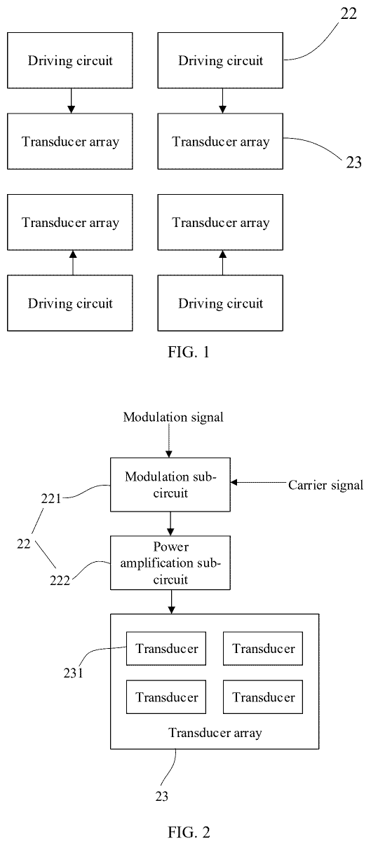

The embodiment of the disclosure provides a sound producing device. As shown in FIG. 1 and FIG. 2, the sound producing device may include a plurality of transducer arrays 23 and a plurality of driving circuits 22.

Each transducer array 23 may include a plurality of transducers 231. The plurality of driving circuits 22 are electrically connected with the plurality of transducer arrays 23 correspondingly, and the plurality of transducers 231 in one transducer array 23 are connected with the same driving circuit 22. The plurality of driving circuits 22 are configured to send preset signals to corresponding transducer arrays 23, the transducer arrays 23 are configured to respond to the preset signals and emit sound waves, and sound wave directions of sound waves emitted by two transducer arrays 23 in the plurality of transducer arrays 23 are different.

According to the sound producing device of the embodiment of the present disclosure, the plurality of driving circuits 22 are correspondingly electrically connected with the plurality of transducer arrays 23, the driving circuits 22 are respectively configured to send preset signals to the corresponding transducer arrays 23, the transducer arrays 23 are configured to respond to the preset signals and emit sound waves, and in the use process, the plurality of driving circuits 22 send the same or different preset signals to the plurality of transducer arrays 23, such that the sound wave directions of the sound waves emitted by the plurality of transducer arrays 23 are different, thereby broadening the application range of the sound producing device.

The sound producing device of the present disclosure will be described in detail below.

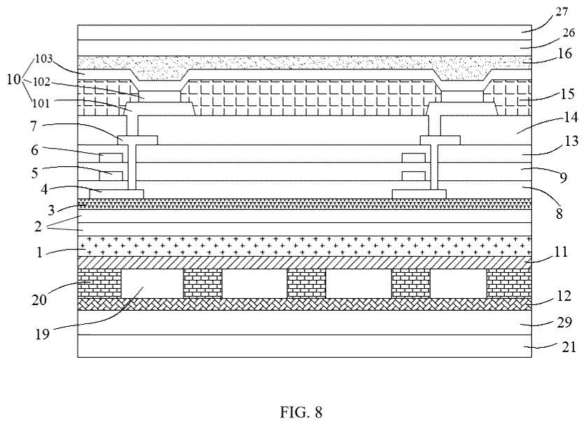

As shown in FIG. 7 and FIG. 8, each transducer 231 may include a first electrode 11, a second electrode 12, and a vibration film 17. The first electrode 11 and the second electrode 12 may be disposed opposite to each other and spaced apart from each other to form a vibration cavity between the first electrode 11 and the second electrode 12. The vibration cavities of the plurality of transducers 231 in one transducer array 23 are communicated. The vibration cavities of the transducers 231 in different transducer arrays 23 are not communicated. The vibration film 17 may be on the second electrode 12 and away from the first electrode 11, in other embodiments, the vibration film 17 may be on the first electrode 11 and away from the second electrode 12, but the disclosure is not limited thereto, and the vibration film 17 may be between the first electrode 11 and the second electrode 12. The transducer 231 may generate sound waves through piezoelectric effect, in some embodiments, the first electrode 11 and the second electrode 12 may generate an electric field, and the vibration film 17 may deform and vibrate under the action of the electric field, thereby generating sound waves.

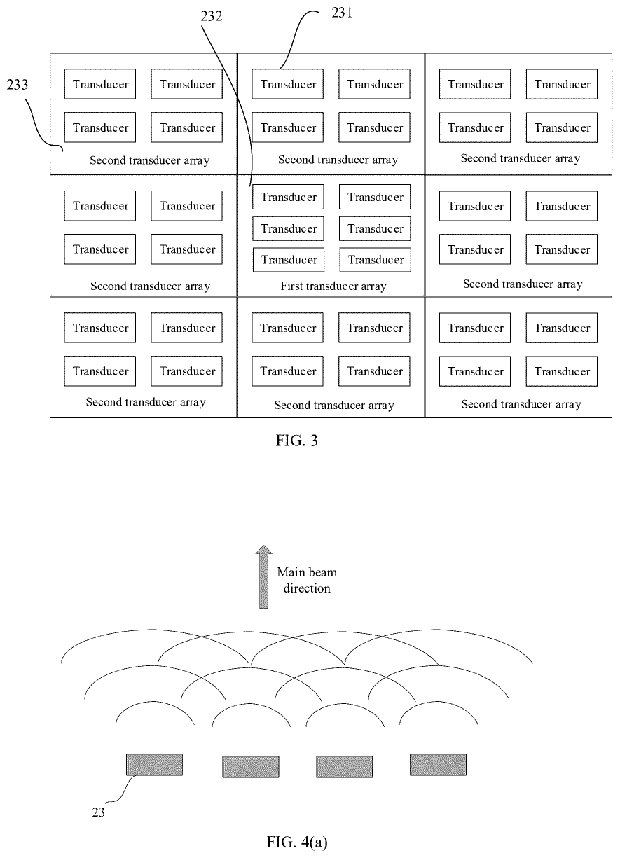

As shown in FIG. 2, FIG. 3 and FIG. 7, one transducer array 23 may include a plurality of transducers 231 arranged in an array. the plurality of transducers 231 in one transducer array 23 may share one vibration film 17. In some embodiments, the plurality of transducer arrays 23 may also share one vibration film 17. As shown in FIG. 3, the plurality of transducer arrays 23 may include a first transducer array 232 and a plurality of second transducer arrays 233. The plurality of second transducer arrays 233 may surround the first transducer array 232. For example, the plurality of transducer arrays 23 includes one first transducer array 232 and eight second transducer arrays 233. In some embodiments, the number of transducers 231 in the first transducer array 232 is greater than the number of transducers 231 in the second transducer array 233. In an embodiment, an area occupied by the first transducer array 232 is same as an area occupied by the second transducer array 233, and a density of the transducers 231 in the first transducer array 232 is greater than a density of the transducers 231 in the second transducer array 233. In another embodiment, the area occupied by the first transducer array 232 is greater than the area occupied by the second transducer array 233, and the density of the transducers 231 in the first transducer array 232 is greater than or equal to the density of the transducers 231 in the second transducer array 233.

As shown in FIG. 2, the driving circuit 22 may include a modulation sub-circuit 221 and a power amplification sub-circuit 222. The modulation sub-circuit 221 configured to receive a modulation signal and a carrier signal, and output a modulated signal according to the modulation signal and the carrier signal. In some embodiments, the modulation sub-circuit 221 configured to, according to the modulation signal, change a parameter of the carrier signal, such as an amplitude, a frequency, and a phase, such that the carrier signal forms a modulated signal. The power amplification sub-circuit 222 is electrically connected with the modulation sub-circuit 221 and configured to receive the modulated signal and output the preset signal according to the modulated signal.

As shown in FIG. 1, the plurality of driving circuits 22 are electrically connected with the plurality of transducer arrays 23 correspondingly, in some embodiments, the plurality of driving circuits 22 are electrically connected with the plurality of transducer arrays 23 in one-to-one correspondence, and the plurality of transducers 231 in one transducer array 23 are connected with the same driving circuit 22. The sound producing device may further include a plurality of first wires 28 (see FIG. 7), the plurality of first wires 28 may be electrically connected with the plurality of transducer arrays 23 in one-to-one correspondence, and the plurality of first wires 28 may be electrically connected with the plurality of driving circuits 22 in one-to-one correspondence, such that the plurality of driving circuits 22 are electrically connected with the plurality of transducer arrays 23 in one-to-one correspondence. Taking the driving circuit 22 including the modulation sub-circuit 221 and the power amplification sub-circuit 222 as an example, the power amplification sub-circuit 222 is electrically connected with the transducer array 23 through the first wiring 28.

As shown in FIG. 7, taking the transducer 231 including the first electrode 11 and the second electrode 12 as an example, the driving circuit 22 may be electrically connected with the second electrode 12 of the transducer 231 through the first wiring 28, such that the driving circuit 22 sends the preset signal to the second electrode 12. The first electrodes 11 of the plurality of transducers 231 may be connected with a stable power supply, a constant potential may be provided to the first electrodes 11 through the stable power supply. The first electrodes 11 of all the transducers 231 in the plurality of transducer arrays 23 may be connected to a same stable power supply, but the present disclosure is not limited thereto.

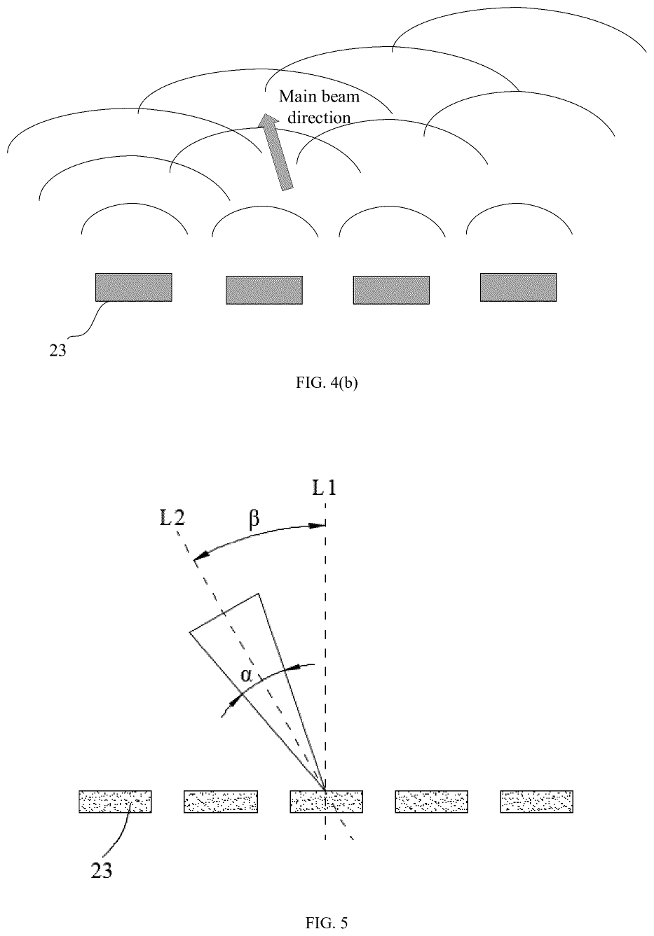

There are two transducer arrays 23 in the plurality of transducer arrays 23 emit different sound waves, for example, beam widths and/or beam deflection angles of the sound waves are different, phases and/or amplitudes of the sound waves are different, and sound wave directions of the sound waves are different. In some embodiments, sound waves emitted by the plurality of transducer arrays 23 are different. By controlling the beam widths and/or beam deviation angles of the sound waves emitted by the plurality of transducer arrays 23, in the present disclosure, the sound waves emitted by the plurality of transducer arrays 23 can face one target object, such that the sound has directionality, thereby realizing fixed-point sounding. It should be noted that phases and/or amplitudes of sound waves generated by the plurality of transducers 231 in one transducer array 23 are the same. As shown in FIG. 4(a) and FIG. 4(b), the sound wave beams emitted by the plurality of transducer arrays 23 are a result of superposition of vibration waves generated by respective transducer arrays 23. Compared with FIG. 4(a), the phase and intensity of the vibration wave generated by the transducer array 23 in FIG. 4(b) are changed, thereby causing the advancing direction of the main beam to change. As shown in FIG. 5, L1 is a plane normal of the vibration source (the transducer array 23), and L2 is a main beam advancing direction; the beam width of the sound wave refers to an angle a at which the intensity is reduced by 50% compared with the intensity of the main beam; and the beam deviation angle of the sound wave refers to an angle β between the main beam advancing direction and the plane normal of the vibration source.

In addition, preset signals sent by two driving circuits 22 in the plurality of driving circuits 22 are different, such that sound waves sent by two transducer arrays 23 electrically connected with the two driving circuits 22 are different. In the present disclosure, in order to change the preset signals, the carrier signal and/or the modulation signal received by the modulation sub-circuit 221 may be adjusted.

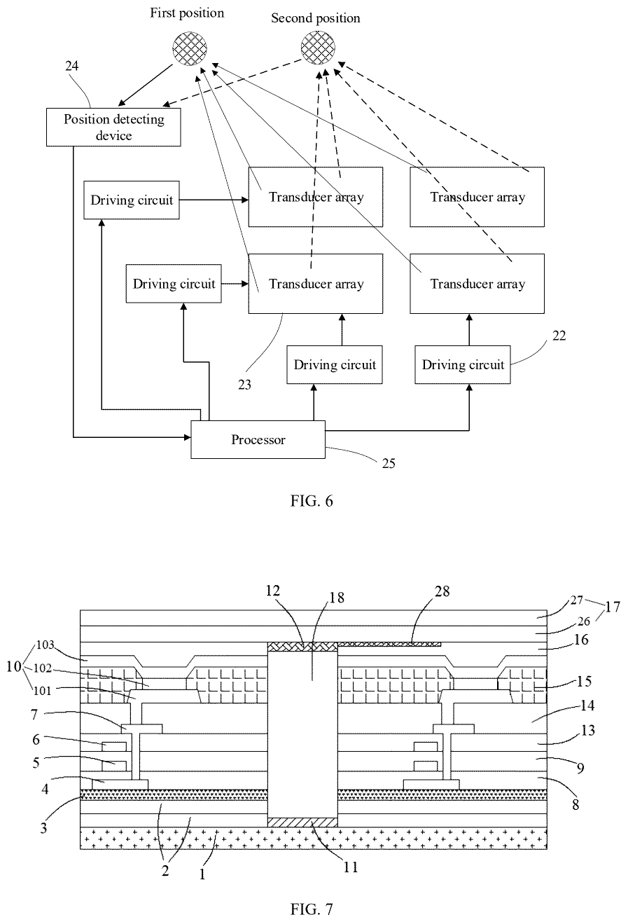

In addition, as shown in FIG. 6, the sound producing device may further include a position detection device 24 and a processor 25. The position detection device 24 is configured to obtain position information of a target object. The position detection device 24 may be a camera, a position sensor, or the like. The processor 25 is electrically connected with the position detection device 24 and the driving circuits 22, and is configured to control the driving circuits 22 to send preset signals to the plurality of transducer arrays 23 according to the position information, such that the plurality of transducer arrays 23 emit sound waves toward the target object. When the target object is at the first position, the position detection device 24 sends detected position information to the processor 25, and the processor 25 controls the plurality of transducer arrays 23 to emit sound waves toward the target object; when the target object moves from the first position to the second position, the position detection device 24 sends detected new position information to the processor 25, and the processor 25 controls the plurality of transducer arrays 23 to emit sound waves toward the target object, thereby realizing sound following.

The embodiment of the disclosure further provides a display module. The display module may include the sound producing device in the above embodiments.

As shown in FIG. 7 and FIG. 8, the display module may include a substrate 1 and a display structure. The substrate 1 may be a flexible substrate, such as a polyethylene terephthalate (PET) substrate, a polyethylene naphthalate (PEN) substrate, or a polyimide (PI) substrate.

The display structure may be on the substrate 1. As shown in FIG. 7 and FIG. 8, the display structure may include a flexible substrate 2 and a pixel circuit layer. The flexible substrate 2 may be a polyethylene terephthalate (PET) substrate, a polyethylene naphthalate (PEN) substrate, or a polyimide (PI) substrate. In addition, there are two flexible substrates 2 stacked arranged.

As shown in FIG. 7 and FIG. 8, the pixel circuit layer is on the flexible substrate 2 and away from the substrate 1. The pixel circuit layer may include a driving transistor. The driving transistor may be a thin film transistor, but the embodiments of the present disclosure are not limited thereto. The thin film transistor may be a top-gate thin film transistor, the thin film transistor may also be a bottom-gate thin film transistor. Taking the thin film transistor being the top-gate thin film transistor as an example, the thin film transistor may include an active layer 4, a first gate insulation layer 8, a first gate electrode layer 5, a second gate insulation layer 9, a second gate electrode layer 6, an interlayer insulation layer 13, and a source-drain electrode layer 7. The active layer 4 may be on the flexible substrate 2. The first gate insulation layer 8 may be on the flexible substrate 2 and cover the active layer 4. The first gate electrode layer 5 may be on the first gate insulation layer 8 and away from the flexible substrate 2. The second gate insulation layer 9 may be on the first gate insulation layer 8 and cover the first gate electrode layer 5. The second gate electrode layer 6 may be on the second gate insulation layer 9 and away from the flexible substrate 2. The interlayer insulation layer 13 may be on the second gate insulation layer 9 and cover the second gate electrode layer 6. The source-drain electrode layer 7 may be on the interlayer insulation layer 13 and connected with the active layer 4 through vias passing through the interlayer insulation layer 13, the first gate insulation layer 8 and the second gate insulation layer 9. In addition, a buffer layer 3 may be between the flexible substrate 2 and the pixel circuit layer.

As shown in FIG. 7 and FIG. 8, the display structure of the embodiment of the present disclosure may further include a planarization layer 14 and a pixel defining layer 15. The planarization layer 14 may cover the source-drain electrode layer 7 and the interlayer insulation layer 13. The pixel defining layer 15 may be on a surface of the planarization layer 14 and away from the flexible substrate 2. The pixel defining layer 15 may be provided with a plurality of pixel openings. The display structure of the present disclosure may further include a light emitting device 10. The light emitting device 10 may be an organic electroluminescent device. The light emitting device 10 may include an anode 101 and a cathode 103 disposed opposite to each other, and a light emitting layer 102 between the anode 101 and the cathode 103. The anode 101 may be in the plurality of pixel openings and electrically connected with the source-drain electrode layer 7 through via holes passing through the planarization layer 14, that is, the pixel defining layer 15 surrounds the light emitting device 10. The light-emitting layer 102 may be on the anode 101 and away from the flexible substrate 2, and the cathode 103 may be on the light-emitting layer 102 and away from the flexible substrate 2. The display structure of the embodiment of the present disclosure may further include an encapsulation layer 16. The encapsulation layer 16 may cover the light emitting device 10.

In an embodiment, as shown in FIG. 7, the display structure may be provided with a first through hole 18 exposing the substrate 1. The first through hole 18 may be spaced apart from the pixel opening, and the first through hole 18 may be spaced apart from the light-emitting layer 102. The first through hole 18 may penetrate the flexible substrate 2, the buffer layer 3, the first gate insulation layer 8, the second gate insulation layer 9, the interlayer insulation layer 13, the planarization layer 14, the pixel defining layer 15, and the encapsulation layer 16. The first through hole 18 may be a square hole, a rectangular hole, a circular hole, an oval hole, or the like. The first through hole 18 may form a vibration cavity of the transducer 231. There are a plurality of first through holes 18, and the plurality of first through holes 18 form vibration cavities of the plurality of transducers 231 in one-to-one correspondence. The display structure may include a display area and a peripheral area surrounding the display area. The light-emitting layer 102 is in the display area. At least part of the plurality of first through holes 18 are in the display area, that is, at least part of the plurality of transducers 231 are in the display area. In addition, the first through holes 18 corresponding to the plurality of transducers 231 in one transducer array 23 are communicated, and the first through holes 18 corresponding to the transducers 231 in different transducer arrays 23 are not communicated.

The first electrode 11 of the transducer 231 may be in a region of the substrate 1 exposed through the first through hole 18. The vibration film 17 may be on the display structure and away from the substrate 1. The vibration film 17 may cover the first through hole 18, that is, an orthographic projection of the first through hole 18 onto the flexible substrate 2 may be within an orthographic projection area of the vibration film 17 onto the flexible substrate 2. The second electrode 12 may be on the vibration film 17 and facing the display structure and in a region of the vibration film 17 corresponding to the first through hole 18. In other embodiments, the second electrode 12 may be on the vibration film 17 and away from the display structure. The plurality of transducers 231 may share one vibration film 17, but the present disclosure is not limited thereto. The vibration film 17 may include a polarizer 26 and/or a cover plate 27, that is, the polarizer 26 and/or the cover plate 27 may form at least part of the vibration film 17. The plurality of driving circuits 22 may be in a peripheral region. A partial region of the first wiring 28 may be between the vibration film 17 and the display structure.

In another embodiment, as shown in FIG. 8, the display module of the present disclosure may include a support structure 20. In FIG. 8, the first electrode 11 may be on the substrate 1 and away from the display structure, the support structure 20 may be on the first electrode 11 and away from the substrate 1, and the support structure 20 is provided with a second through hole 19 exposing the first electrode 11. The second through hole 19 may be a square hole, a rectangular hole, a circular hole, an oval hole, or the like. The second through hole 19 may form a vibration cavity of the transducer 231. There are a plurality of second through holes 19, and the plurality of second through holes 19 may form vibration cavities of the plurality of transducers 231 in one-to-one correspondence. The second through holes 19 corresponding to the plurality of transducers 231 in one transducer array 23 are communicated, and the second through holes 19 corresponding to the transducers 231 in different transducer arrays 23 are not communicated. In addition, the first electrodes 11 corresponding to the plurality of transducers 231 in one transducer array 23 may be of an integrated structure, and the first electrodes 11 corresponding to different transducer arrays 23 may be insulated or spaced apart. In some embodiments, the first electrodes 11 corresponding to the plurality of transducer arrays 23 may be of an integrated structure. The second electrode 12 is on the support structure 20 and away from the substrate 1 and covers the second through hole 19. The first electrodes 11 corresponding to the plurality of transducers 231 in one transducer array 23 may be of an integral structure, and the first electrodes 11 corresponding to the plurality of transducers 231 in different transducer arrays 23 may be insulated or spaced apart. The display module may further include a stress relief layer 29. The stress relief layer 29 may be on the second electrode 12 and away from the substrate 1. In addition, the display module may further include a stainless steel support layer 21. The stainless steel support layer 21 may be on the stress relief layer 29 and away from the substrate 1. A distance between a surface of the stress relief layer 29 facing the substrate 1 and a surface of the stainless steel support layer 21 facing away from the substrate 1 is 150 μm-300 μm, that is, a sum of a thickness of the stainless steel support layer 21 and a thickness of the vibration film 17 may be 150 μm-300 μm. The thickness of the support structure 20 may be 5 μm-20 μm. The thickness of the support structure 20 refers to the size of the support structure 20 in the thickness direction of the flexible substrate 2. The display structure of the embodiment of the present disclosure may include a polarizer 26 on the encapsulation layer 16 and a cover plate 27 on the polarizer 26. A distance between a surface of the polarizer 26 facing away from the flexible substrate 2 and a surface of the flexible substrate 2 facing the substrate 1 may be 50 μm-200 μm.

Embodiments of the present disclosure further provide a display device. The display device may include the display module according to any one of the above embodiments. The display device may be a mobile phone, or may be a tablet computer, a television, or the like.

The display device, the display module and the sound producing device provided by the embodiments of the present disclosure belong to the same inventive concept, and the description of related details and beneficial effects may be referred to each other, which will not be repeated.

The above is only some embodiments of the present disclosure, and is not intended to limit the present disclosure in any form, although the present disclosure has been disclosed in the embodiments, it is not intended to limit the present disclosure, and any person skilled in the art may make some changes or modifications to equivalent embodiments without departing from the scope of the technical solutions of the present disclosure, but any simple modifications, equivalent modifications and modifications made to the above embodiments according to the technical substance of the present disclosure are still within the scope of the technical solutions of the present disclosure without departing from the content of the technical solutions of the present disclosure.

1. A sound producing device, comprising:
a plurality of transducer arrays each comprising a plurality of transducers; and
a plurality of driving circuits respectively electrically connected to the plurality of transducer arrays, and the plurality of transducers in one of the transducer arrays are connected to a same driving circuit;
wherein the plurality of driving circuits are respectively configured to send preset signals to the corresponding transducer arrays, the plurality of transducer arrays are configured to respond to the preset signals and emit sound waves, and sound wave directions of sound waves emitted by two transducer arrays in the plurality of transducer arrays are different.

2. The sound producing device according to claim 1, wherein the plurality of transducer arrays comprise a first transducer array and a plurality of second transducer arrays, the plurality of second transducer arrays surround the first transducer array, and a number of the transducers in the first transducer array is greater than a number of the transducers in the second transducer array.

3. The sound producing device according to claim 1, wherein each of the plurality of driving circuits comprises:
a modulation sub-circuit configured to receive a modulation signal and a carrier signal and output a modulated signal according to the modulation signal and the carrier signal; and
a power amplification sub-circuit configured to receive the modulated signal and output the preset signal according to the modulated signal.

4. The sound producing device according to claim 1, further comprising:
a position detection device configured to acquire position information of a target object; and
a processor, electrically connected to the position detection device and the plurality of driving circuits, and configured to control the plurality of driving circuits to send the preset signals to the plurality of transducer arrays according to the position information, such that the plurality of transducer arrays send sound waves toward the target object.

5. A display module, comprising a sound producing device wherein the sound producing device comprises:
a plurality of transducer arrays each comprising a plurality of transducers; and
a plurality of driving circuits respectively electrically connected to the plurality of transducer arrays, and the plurality of transducers in one of the transducer arrays are connected to a same driving circuit;
wherein the plurality of driving circuits are respectively configured to send preset signals to the corresponding transducer arrays, the plurality of transducer arrays are configured to respond to the preset signals and emit sound waves, and sound wave directions of sound waves emitted by two transducer arrays in the plurality of transducer arrays are different.

6. The display module according to claim 5, wherein each transducer of the plurality of transducers comprises a first electrode, a second electrode and a vibration film, wherein the first electrode and the second electrode are disposed opposite to each other and are spaced apart from each other, a space between the first electrode and the second electrode forms a vibration cavity of the transducer, and the display module comprises:
a substrate; and
a display structure on the substrate, the display structure being provided with a plurality of first through holes exposing the substrate, the plurality of first through holes correspondingly forming vibration cavities of the plurality of transducers;
wherein the first electrode is in a region of the substrate exposed through the first through hole; the vibration film is on the display structure and away from the substrate and covers the first through hole; and the second electrode is on the vibration film facing or facing away from the display structure and in a region of the vibration film corresponding to the first through hole.

7. The display module according to claim 6, wherein each driving circuit of the plurality of driving circuits is electrically connected with the second electrode through a first wiring, and a partial region of the first wiring is between the vibration film and the display structure.

8. The display module according to claim wherein the plurality of transducers share one vibration film, and the vibration film comprises a polarizer and/or a cover plate.

9. The display module according to claim 6, wherein the display module comprises a display area and a peripheral area, the plurality of driving circuits are in the peripheral area, and at least part of the plurality of transducers are in the display area.

10. The display module according to claim 5, wherein each transducer of the plurality of transducers comprises a first electrode, a second electrode and a vibration film, wherein the first electrode and the second electrode are disposed opposite to each other and are spaced apart from each other, a space between the first electrode and the second electrode forms a vibration cavity of the transducer, and the display module comprises:
a substrate;
a display structure on the substrate, the display structure forming at least part of the vibration film, the first electrode being on the substrate and away from the display structure; and
a support structure on the first electrode and away from the display structure, wherein the support structure is provided with a plurality of second through holes exposing the first electrode, and each second through hole forms a vibration cavity of the transducer, and the second electrode is on the support structure and away from the substrate and covers the second through hole.

11. The display module according to claim 10, further comprising:
a stress relief layer on the second electrode and away from the substrate; and
a stainless steel support layer on the stress relief layer and away from the substrate.

12. The display module according to claim 11, wherein a thickness of the support structure is 5 μm-20 μm;

13. The display module according to claim wherein the display structure comprises:
a flexible substrate on the substrate;
a pixel circuit layer on the flexible substrate and away from the substrate;
a plurality of organic electroluminescent devices on the pixel circuit layer and away from the flexible substrate;
a pixel defining layer surrounding the plurality of organic electroluminescent devices; and
an encapsulation layer covering the plurality of organic electroluminescent devices.

14. The display module according to claim 13, wherein a distance between a surface of the flexible substrate facing the substrate and a surface of the polarizer facing away from the substrate is 50 μm-200 μm.

15. The display module according to claim wherein the vibration cavities of the plurality of transducers in one of the transducer arrays are communicated.

16. A display device, comprising the display module according to claim 5.

17. The display module according to claim 11, wherein a distance between a surface of the stress relief layer facing the substrate and a surface of the stainless steel support layer facing away from the substrate is 150 μm-300 μm.

18. The display module according to claim 13, wherein the display module further comprises a polarizer on the encapsulation layer and away from the flexible substrate.

19. The display module according to claim 6, wherein the vibration cavities of the plurality of transducers in different transducer arrays are not communicated.
